(19) United States
(12) Patent Application Publication
(10) Pub. No.: US 2011/0101440 A1
(43) Pub. Date: May 5, 2011

(54) TWO PFET SOI MEMORY CELLS

(75) Inventors: Jin Cai, Hopewell Junction, NY (US); Brian L. Ji, Fishkill, NY (US); Tak Hung Ning, Yorktown Heights, NY (US)

(73) Assignee: INTERNATIONAL BUSINESS MACHINES CORPORATION, Armonk, NY (US)

(21) Appl. No.: 12/612,710

(22) Filed: Nov. 5, 2009

(51) Int. Cl. H01L 27/092; H01L 21/8238

(52) U.S. Cl. 257/319; 438/211; 257/E27.062; 257/E21.632

(57) ABSTRACT

A CMOS device includes a silicon substrate and an electrical insulator formed over the silicon substrate. The device also includes an access pFET formed over the electrical insulator and a first gate stack and a storage pFET formed over the electrical insulator, the storage pFET including a second source region that is co-formed with the first drain region, a second channel region, and a second drain region. The device also includes a second gate stack including a second dielectric layer formed above the second channel region and a floating gate electrode formed above the second gate dielectric layer.

### BACKGROUND

The present invention relates to memory cells, and more specifically, to SOI memory cells.

This invention relates to Complementary Metal-Oxide-Semiconductor (CMOS) Electrically Programmable Read Only Memory (EPROM) and CMOS EEPROM (Electrically Erasable and Programmable Read Only Memory) devices.

In many applications, particularly in System-on-Chip (SoC) applications, designers want to have a certain number of embedded non-volatile memory devices on the microprocessor or Application-Specific Integrated Circuit (ASIC) chips. One approach for meeting this need is to provide embedded non-volatile memories that require little or no additional processing cost to the base logic technology. Often, the additional requirements for such embedded non-volatile memories are high density, i.e. small cell size, low power, and high speed.

In a regular CMOS logic process, non-volatile memory devices are typically store charge in a floating gate electrode. In general, it takes a lower voltage to inject hot electrons from silicon into a floating gate electrode than to inject electrons from silicon into a floating gate electrode by Fowler-Nordheim tunneling. As a result, for high-speed and low-voltage operation, hot electron injection is typically used.

Floating gate Field Effect Transistors (FETs) including a control gate are well known. A floating gate electrode differs from a control gate electrode in that it has no direct electrical connection to any external component and is surrounded by isolation on all sides. In a typical floating gate FET including a control gate, the control gate is positioned on top of the floating gate. The presence of a control gate electrode enables an FET device to function as a regular FET, while a floating gate electrode collects and stores injected electrons or holes. The floating gate electrode provides a method for changing the threshold voltage needed to pass a charge from the source region of the FET to the drain region thereof. The presence of the control gate electrode adds control to the injection of charges into and out of the floating gate region of the FET, thus enabling the FET device to function as an electrically programmable or reprogrammable memory device.

Source-side injection flash cells or split gate flash cells are commonly used as embedded flash memories. In a split gate cell, the floating gate overlies only a portion of the channel and the control gate electrode overlies both the floating gate electrode and the remainder of the channel. In other words, there are two transistors in series between a source and a drain. One relatively popular flash cell employs oxidized polysilicon to create sharp points in the polysilicon in order to enhance the electric field. This in turn allows erasure at lower voltages and provides for thicker dielectric layers between the floating gate electrode and the control gate electrode. The LOCalized Oxidation of Silicon (LOCOS) process is commonly used for fabricating such cells to form an insulator cap over the polysilicon of the floating gate electrode. The LOCOS process creates sharp points on the floating gate electrode, resulting in a bird's beak structure.

Nevertheless, the existing flash memory cells exhibit two major shortcomings which are high programming voltage required and non-planar cell topography due to the presence of the floating gate electrode.

In a floating gate device, electrons are injected into the floating gate electrode, either by hot electron injection or by electron tunneling (Fowler-Nordheim or F-N tunneling). In the case of hot electron injection, it is well-known that it is much more efficient to use avalanche hot electron injection using a p-channel FET device than to use channel hot electron injection using an n-channel FET device. For embedded applications, it is desirable to use an access or select transistor connected in series with the memory element to form the non-volatile memory cell. While adding a select transistor adds area to the memory cell, the use of a select transistor avoids many issues of operation of a true single-device memory cell with no access transistor. For example, such an access transistor guarantees that there is no over-erase problem, and avoids disturbing the non-selected cells.

For the select transistor, it is desirable to use an n-channel FET, instead of a p-channel FET, because an n-channel FET typically has twice the performance as a p-channel FET due to higher electron mobility. In other words, it is desirable to have a CMOS non-volatile memory device where the n-channel FET is used as an access transistor and the floating-gate p-channel FET is used as the memory element.

To reduce cell area in bulk CMOS implementations, a p-FET is usually used for an access transistor instead of an n-FET. Such an all p-FET bulk CMOS implementation is shown in FIG. 1.

FIG. 1 is a schematic diagram of a cross section of a prior art MOS FET EPROM device 30 comprising a bulk pFET 31 and another bulk pFET 33, without any n-FET devices, formed on an N-well 39. The N-well 39 is centered between the right edge of a left isolation oxide region 35L and the left edge of a right isolation oxide region 35R. The pFET 31, which is formed adjacent to the left isolation oxide region 35L, is composed of an p+ doped source region 32(S), an n doped channel region CH1 and the left half of a shared, p+ doped region 37. The pFET 33 is composed of the right hand half of the shared, p+ doped region 37, an n doped channel region CH2 and a p+ drain region 36(D) formed between the pFET 31 and the right isolation oxide region 35R. The shared, p+ region 37 is the source for the pFET device 33. For a pFET, the region with more positive voltage is the source and the region with the less positive voltage is the drain, visa versa for an nFET. For two pFETs in series, as in FIG. 1, the most positive voltage (Vdd) is applied to region 32(S), or the source of pFET 31, via select line SL and the region 37 is the drain of pFET device 31 as well as the source of the pFET device 33. The p+ drain region 36(D) is the drain of pFET device 33.

The pFET 31 includes a thin gate dielectric (gate oxide) layer 23 formed over the first channel region CH1 of the pFET 31 and a gate electrode 34, which is electrically conductive, located above the thin gate dielectric layer 23.

The pFET 33 includes a first thick gate dielectric (e.g. silicon oxide) layer 25F, formed over the n doped channel region CH2 of the pFET 33, and a first floating gate electrode FG1, which is also electrically conductive, located above the first thick gate dielectric layer 25F. The thick gate dielectric layer 25F must be sufficiently thick to prevent leakage of charge stored on the floating gate FG1.

### SUMMARY

According to one embodiment of the present invention, a CMOS device that includes a silicon substrate and an electrical insulator formed over the silicon substrate is disclosed. The device also includes an access pFET formed over the electrical insulator including a first source region, a first channel region, and a first drain region. The device also includes a first gate stack including a first dielectric layer formed over the first channel region and a gate electrode formed above said gate dielectric layer and a storage pFET formed over the electrical insulator, the storage pFET including a second source region that is co-formed with the first drain region, a second channel region, and a second drain region. The device also includes a second gate stack including a second dielectric layer formed above the second channel region and a floating gate electrode formed above the second gate dielectric layer.

According to another embodiment, a method of forming a CMOS device that includes providing a silicon substrate; forming an electrical insulator over the silicon substrate; forming an access pFET over the electrical insulator that includes a first source region, a first channel region, a first drain region; forming a first gate stack including a first dielectric layer formed over the first channel region and a gate electrode formed above said first gate dielectric layer; forming a storage pFET over the electrical insulator, the storage pFET including a second source region that is co-formed with the first drain region, a second channel region, and a second drain region; and forming a second gate stack including a second dielectric layer above the second channel region and a floating gate electrode formed above the second gate dielectric layer.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a schematic diagram of a cross section of a prior art MOS FET EPROM device;

FIG. 2 is a schematic diagram of a cross section of a memory cell according to one embodiment of the present invention; and

FIG. 3 is a schematic diagram of a cross section of a memory cell according to another embodiment of the present invention.

### DETAILED DESCRIPTION

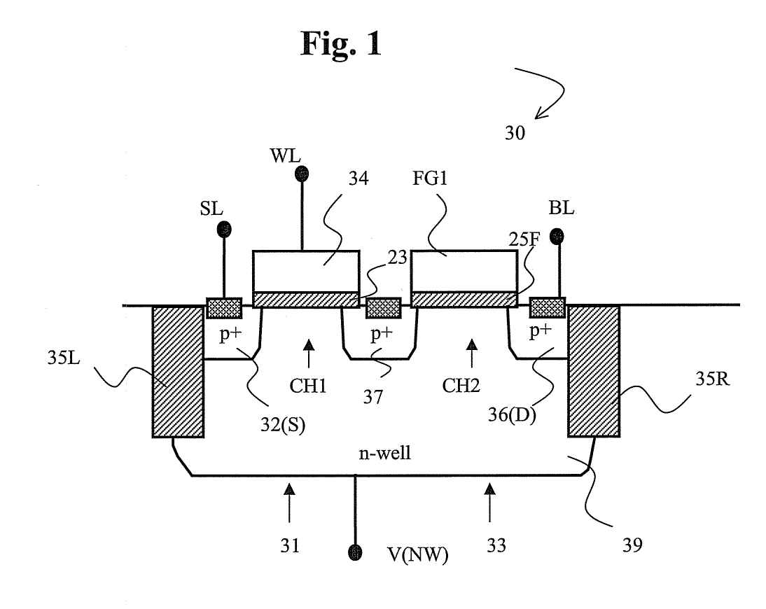

Referring again to FIG. 1, programming of such memory cell may lead to unwanted effects. In particular, the voltage of the n-well 39 (Vnw) will vary depending on the location where it is measured. In this example, pFET 31 is the access transistor and pFET 33 is the storage cell. The storage cell 33 is programmed by avalanche hot electron injection into the floating gate. Typically a large negative voltage is applied to the bitline (BL), a negative voltage to the wordline (WL) to turn on the access transistor, while the select line (SL) is held at ground. Avalanche occurs in the n-well 39 near the bitline diffusion region. The electrons from avalanche flow in the n-well 39 away from the p-region 36(D) and toward the connection providing the voltage Vnw to the n-well 39, causing an IR drop in the n-well 39. This IR drop has the effect of forward biasing the p-n junction formed between the p+ doped source region 32(S) and the n-well 39, causing a reduction of the Vt of the access pFET 31 (and every pFET sharing the same n-well). The amount of Vt reduction depends on the avalanche current and the position of the affected pFET relative to the diffusion region where avalanche takes place. This Vt variation caused by the avalanche current makes it more challenging to design the bulk version. It limits the voltage applied to cause avalanche because the larger the avalanche current the larger the undesirable IR drop in the n-well. This unintended position-dependent IR drop in the n-well makes it difficult, if not impossible, to achieve multi-level storage in this bulk cell.

Embodiment of the present invention may overcome one or more of the problems described above. In general, the present invention is directed to a silicon on insulator (SOI) EEPROM cell that includes 2 SOI pFETS. In contrast to the embodiment shown in FIG. 1, according to embodiments of the present invention, rather than forming 2 pFETs in a common n-well, the storage (floating gate) pFET is isolated from any other cells. One manner in which this may be accomplished is by forming one or both the access and the storage cells as SOI pFETS.

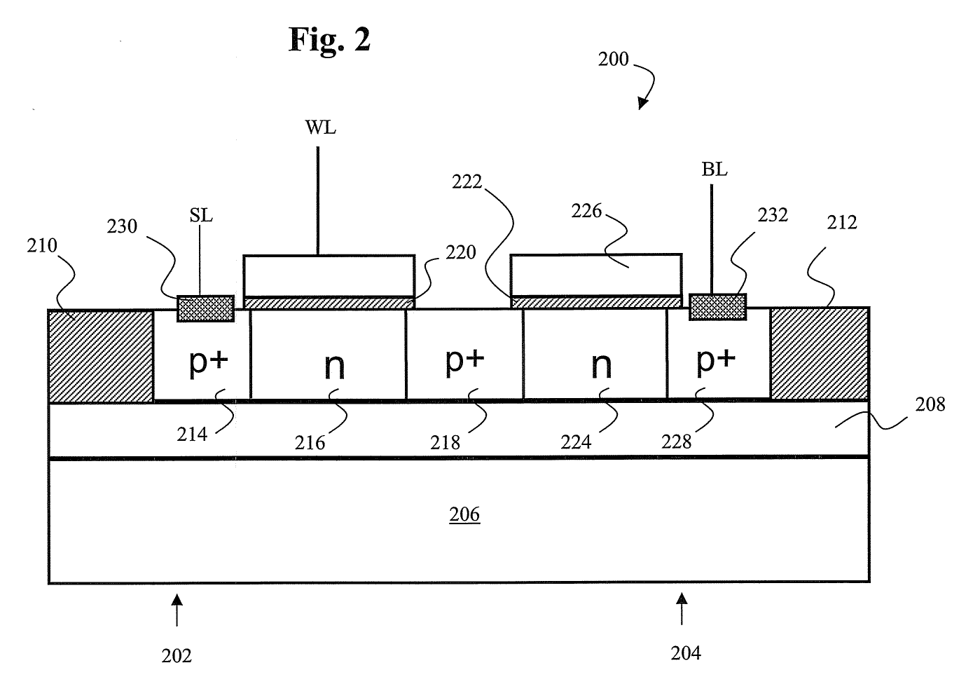

FIG. 2 shows a cut-away side view of a memory cell 200 according to one embodiment. The memory cell 200 may, in one embodiment, be a CMOS EEPROM memory cell. The memory cell 200 includes an access pFET 202 and a storage pFET 204. The memory cell 200 is formed in a silicon on insulator arrangement. Silicon on insulator technology (SOI) refers to the use of a layered silicon-insulator-silicon substrate in place of conventional silicon substrates in semiconductor manufacturing, especially microelectronics, to reduce parasitic device capacitance and thereby improving performance. SOI-based devices differ from conventional silicon-built devices in that the silicon junction is above an electrical insulator, typically silicon dioxide or (less commonly) sapphire. In particular, the memory cell 200 includes a silicon substrate 206. An insulator layer 208 is disposed over the silicon substrate 206. The insulator layer 208 is often referred to as a Buried Oxide (BOX) layer.

In one embodiment, the access pFET 202 and the storage pFET 204 that comprise the memory cell 200 are disposed between a left isolation oxide region 210 and a right isolation oxide region 212. These regions may be formed, for example, on a top side of the insulator layer 208.

The access pFET 202 includes a p doped source 214 separated from a p doped drain 218 by a first channel 216. The first channel 216 is n type region. Alternatively, the first channel 216 can be an undoped region, with no intentionally added dopant. The first channel 216 has a gate layer 220 disposed on top of it. The gate layer 220 may be a thin dielectric layer. The p doped drain 218 of the access pFET 202 also serves as the source of the storage pFET 204.

The storage pFET 204 may be formed as a floating gate pFET. In a particular embodiment, the storage pFET 204 includes a floating gate dielectric (silicon oxide) layer 222, formed over the n doped channel region 224. Alternatively, the channel region 224 can be undoped, with no intentionally added dopant. The floating gate dielectric layer 222 is of sufficient thickness to prevent leakage of charge stored on a floating gate electrode 226 by unwanted tunneling of charge therethrough. The floating gate electrode 224, located above the gate dielectric layer 222, is also electrically conductive.

The storage pFET 204 also includes a source 218 (co-formed with the drain of the access pFET 202) and a drain 228 separated from the source 218 by the second channel 224. In one embodiment, the source 218, channel 224 and the drain 228 are all formed on top of the insulating layer 208 and do not contact the substrate 206.

A first silicided contact 230, formed on the top surface of the source region 214 of the access pFET 202, is connected to the select line SL and a second silicided contact 232, which is formed on the top surface of the drain region 228 of the storage pFET 204, is connected to the bit line BL. The gate of the access pFET 202 is coupled to a word line WL.

To program the memory cell 200, a large negative programming voltage is applied to the bitline BL and the access pFET 202 is turned on with a negative wordline voltage on wordline WL. The select line SL is connected to ground or 0 V, causing a large voltage to be dropped between the source region 218 the drain region 228 of the storage pFET 204. The large programming voltage causes avalanche impact ionization to occur near the drain end of the storage pFET 204, causing secondary hot electrons to be injected into the floating gate electrode 226. As a hot electron current is generated by the injection of those secondary hot electrons into the floating gate electrode 226, the storage pFET 204 begins to turn ON.

As the storage pFET 204 turns ON, at first the hot electron current increases as the current in the channel region 224 of the storage pFET 204 increases, and then the hot electron current begins to decrease once the floating gate 226 is charged to the equivalent of about 0.4 V above the threshold voltage of the storage pFET 204.

Unlike the prior art, however, the extra electrons generated in the avalanche multiplication process are confined to the channel region of the storage pFET and hence are not disposed throughout a common n-well creating a variable voltage in the n well based on location. Accordingly, the extra electrons do not affect other parts of the circuit.

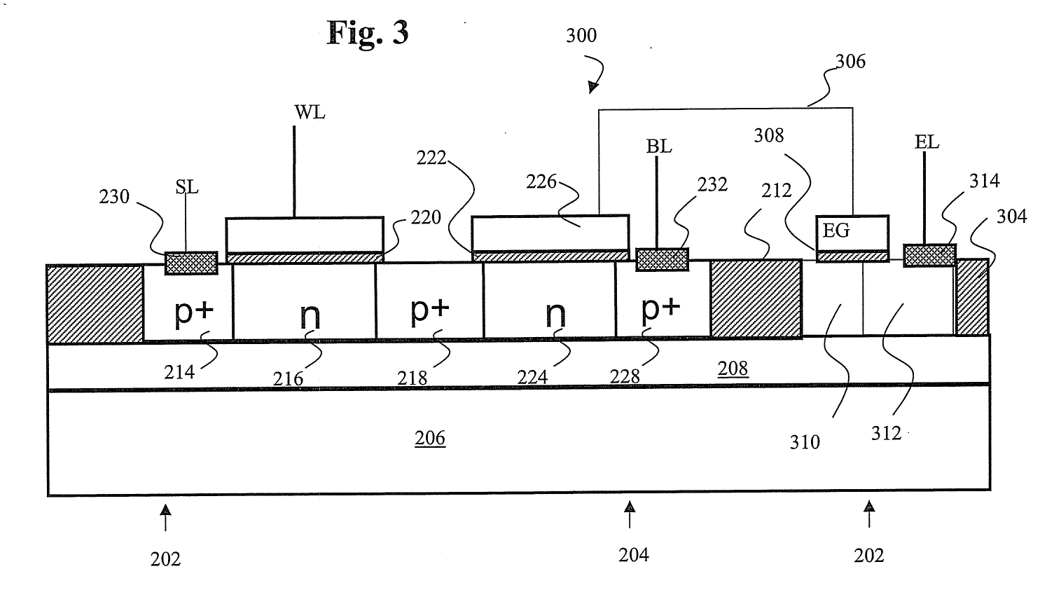

FIG. 3 shows an embodiment comprising a CMOS non-volatile EEPROM cell 300 in accordance with this invention, that is a modification of the memory cell 200 of FIG. 2. This embodiment includes an erase device 302 and incorporates a third isolation oxide region 304 on the top surface of the isolation layer 208, is located to the right of the p+ doped drain region 228 of the storage pFET 204. The third isolation oxide region 304 is juxtaposed with the erase device 302 which has an erase gate electrode EG that is electrically connected by an electrical conductor line 306 to the floating gate electrode 226.

The erase device 302 can be simply one half of an FET with a second thick gate dielectric layer 308 substantially equal in thickness to the thick gate dielectric 222 of the pFET 204. The erase device 302 includes a doped region 310 and an n+ doped region 312 formed in the SOI layer on the top surface of the BOX layer 208. The doped region 310 is juxtaposed with the right edge of right oxide region 212. The n+ doped region 312 is located to the right of the doped region 310 and on the other side is juxtaposed with the left edge of the third isolation oxide region 304. The second thick gate dielectric layer 308 is formed above the doped region 310 and a portion of the n+ doped region 312 with the erase gate electrode EG formed on the top surface thereof with the erase gate electrode EG overlapping the gate-edge-defined n-type diffusion region 312. An erase gate silicided contact 314 is formed over a portion of the n+ doped region 312 and is spaced away from the erase gate electrode EG. In the doped region 310 may be either n or p doped. In summary, in FIG. 3 the erase device 302 includes the doped region 310 (either n or p doped), the n+ doped region 312 formed in the SOI layer, the second thick gate dielectric layer 308 formed above the doped region 310 and the n+ doped region 312 i.e. the erase gate electrode EG is formed over the second thick gate dielectric layer 308.

The memory device 300 can be erased by applying a large positive voltage to the erase line 314 to cause electrons in the floating gate electrode 226 to tunnel out to the erase-line electrode 314. Since there is an access transistor 202 in the memory cell 300, there is no concern of over-erasure.

In the EEPROM cell 300, the erase gate electrode EG is also floating since neither the erase gate electrode EG nor the floating gate electrode 226 is connected to an external terminal. Except for the erase device 302, the cell 300 is otherwise identical in structure to the cell 200 of FIG. 2.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A CMOS device comprising:
a silicon substrate;
an electrical insulator formed over the silicon substrate;
an access pFET formed over the electrical insulator including a first source region, a first channel region, and a first drain region;
a first gate stack including a first dielectric layer formed over the first channel region and a gate electrode formed above said gate dielectric layer;
a storage pFET formed over the electrical insulator, the storage pFET including a second source region that is co-formed with the first drain region, a second channel region, and a second drain region; and
a second gate stack including a second dielectric layer formed above the second channel region and a floating gate electrode formed above the second gate dielectric layer.

2. The CMOS device of claim 1 wherein the device comprises an EPROM memory.

3. The CMOS device of claim 1 wherein the device comprises an EEPROM memory.

4. The CMOS device of claim 1, wherein the electrical insulator is a buried oxide layer.

5. The CMOS device of claim 1, including an erase device with gate dielectric layer formed in parallel with said storage pFET.

6. The CMOS device of claim 5, wherein the erase device includes a second floating gate electrode that is electrically connected to the floating gate electrode of the storage pFET.

7. The CMOS device of claim 5, wherein the erase device is an erase nFET device.

8. The CMOS device of claim 7, wherein the erase nFET device includes a second floating gate electrode that is electrically connected to the floating gate electrode of the storage pFET.

9. The CMOS device of claim 1, wherein the second dielectric layer is thicker than the first dielectric layer.

10. A method of forming a CMOS device, the method comprising:
providing a silicon substrate;
forming an electrical insulator over the silicon substrate;
forming an access pFET over the electrical insulator that includes a first source region, a first channel region, a first drain region;
forming a first gate stack including a first dielectric layer formed over the first channel region and a gate electrode formed above said first gate dielectric layer;
forming a storage pFET over the electrical insulator, the storage pFET including a second source region that is co-formed with the first drain region, a second channel region, and a second drain region; and
forming a second gate stack including a second dielectric layer above the second channel region and a floating gate electrode formed above the second gate dielectric layer.

11. The method of claim 10, wherein the device comprises an EPROM memory.

12. The method of claim 10, wherein the device comprises an EEPROM memory.

13. The method of claim 10, wherein the electrical insulator is a buried oxide layer.

14. The method of claim 10, further comprising:
forming an erase FET device with a gate dielectric layer in parallel with the storage pFET and over the insulating layer.

15. The method of claim 14, wherein the erase FET device includes a second floating gate electrode that is electrically connected to the floating gate electrode of the storage pFET.

16. The method of claim 10, wherein the second dielectric layer is thicker than the first dielectric layer.
